(19) United States
(12) Patent Application Publication
(10) Pub. No.: US 2024/0243702 A1
(43) Pub. Date: Jul. 18, 2024

(54) POWER AMPLIFIER

(71) Applicant: Samsung Electro-Mechanics Co., Ltd., Suwon-si (KR)

(72) Inventors: Kyujin CHOI, Suwon-si (KR); Seungchul PYO, Suwon-si (KR); Kyung Hee HONG, Suwon-si (KR); Geunyong LEE, Suwon-si (KR); Suyeon HAN, Suwon-si (KR); Yoshiyuki TONAMI, Suwon-si (KR)

(73) Assignee: Samsung Electro-Mechanics Co., Ltd., Suwon-si (KR)

(21) Appl. No.: 18/217,055

(22) Filed: Jun. 30, 2023

(30) Foreign Application Priority Data
Jan. 18, 2023 (KR) 10-2023-0007423

(51) Int. Cl. H03F 1/26; H03F 3/21

(52) U.S. Cl. CPC H03F 1/26; H03F 3/211; H03F 2200/451

(57) ABSTRACT

A power amplifier configured to amplify an input radio-frequency (RF) signal includes a first power transistor including an input terminal; a first capacitor having a first end connected to the input terminal of the first power transistor; and a resistor having a first end connected to a second end of the first capacitor and a second end connected to a ground. The input RF signal is input to the second end of the first capacitor and the first end of the resistor.

### CROSS-REFERENCE TO RELATED APPLICATIONS

This application claims the benefit under 35 USC 119(a) of Korean Patent Application No. 10-2023-0007423 filed on Jan. 18, 2023, in the Korean Intellectual Property Office, the entire disclosure of which is incorporated herein by reference for all purposes.

### BACKGROUND OF THE INVENTION

### 1. Field of the Invention

The present disclosure relates to a power amplifier.

### 2. Description of the Related Art

A wireless communication system uses various digital modulation methods according to evolution of communication standards. A conventional code-division multiple access (CDMA) communication system employs a quadrature phase-shift keying (QPSK) method, and a wireless local area network (LAN) according to various IEEE communication standards employs an orthogonal frequency-division multiplexing (OFDM) method. In addition, long-term evolution (LTE) and LTE Advanced (LTE+) that are recent 3GPP standards employ QPSK, quadrature amplitude modulation (QAM), and OFDM methods. These wireless communication standards employ a linear modulation method that requires that an amplitude or a phase of a transmission signal is maintained during transmission.

A transmission device used in the wireless communication system includes a power amplifier that amplifies an input radio-frequency (RF) signal to increase a transmission distance.

In the power amplifier, an undesired low-frequency RF signal may be input to the power amplifier due to internal or external factors. For example, a low-frequency noise and a common mode signal may be input to the power amplifier. The undesired low-frequency input RF signal may cause the power amplifier to oscillate, and thus needs to be reduced.

The above information disclosed in this Background section is only for enhancement of understanding of the background of the disclosure of this application, and therefore it may contain information that does not constitute prior art that is already known to a person of ordinary skill in the art.

### SUMMARY OF THE INVENTION

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a power amplifier configured to amplify an input radio-frequency (RF) signal includes a first power transistor including an input terminal; a first capacitor having a first end connected to the input terminal of the first power transistor; and a resistor having a first end connected to a second end of the first capacitor and a second end connected to a ground, wherein the input RF signal is input to the second end of the first capacitor and the first end of the resistor.

A low-frequency signal including a noise included in the input RF signal may be bypassed to the ground through the resistor.

The low-frequency signal may include either one or both of a low-frequency noise signal and a common mode signal.

The input RF signal may pass through the first capacitor to be input to the input terminal of the first power transistor.

The power amplifier may further include a bias circuit configured to supply a bias current to the input terminal of the first power transistor.

The power amplifier may further include a second power transistor including an input terminal and an output terminal connected to an output terminal of the first power transistor; and a second capacitor connected between the first end of the resistor and the input terminal of the second power transistor.

The input RF signal may pass through the first capacitor to be input to the input terminal of the first power transistor, and may pass through the second capacitor to be input to the input terminal of the second power transistor.

The power amplifier may further include a first bias circuit configured to supply a first bias current to the input terminal of the first power transistor; and second bias circuit configured to supply a second bias current to the input terminal of the second power transistor.

In another general aspect, a power amplifier includes a first power transistor including an input terminal; a second power transistor including an input terminal; a first capacitor having a first end connected to the input terminal of the first power transistor; a first resistor having a first end connected to a second end of the first capacitor and a second end connected to a ground; a second capacitor having a first end connected to the input terminal of the second power transistor; and a second resistor having a first end connected to a second end of the second capacitor and a second end connected to the ground.

The power amplifier may further include an input transformer configured to convert an input radio-frequency (RF) signal to a first differential signal and a second differential signal, wherein the first differential signal may be input to the second end of the first capacitor and the first end of the first resistor, and the second differential signal may be input to the second end of the second capacitor and the first end of the second resistor.

A low-frequency signal including a noise included in the first differential signal may be bypassed to the ground through the first resistor, and a low-frequency signal including a noise included in the second differential signal may be bypassed to the ground through the second resistor.

The low-frequency signal may include either one or both of a low-frequency noise signal and a common mode signal.

The first differential signal may pass through the first capacitor to be input to the input terminal of the first power transistor, and the second differential signal may pass through the second capacitor to be input to the input terminal of the second power transistor.

The power amplifier may further include an output transformer configured to combine an output signal of the first power transistor with an output signal of the second power transistor.

In another general aspect, a power amplifier includes a first power transistor configured to amplify an input radio-frequency (RF) signal to produce a first amplified output RF signal and including a first input terminal configured to receive the input RF signal, and a first output terminal configured to output the first amplified output RF signal; a first element having an impedance value that decreases as frequency increases and having a first end connected to the first input terminal of the first power transistor; and a second element having an impedance value that is substantially independent of frequency and having a first end connected to a second end of the first element and a second end connected to a ground.

A low-frequency signal included in the input RF signal may be bypassed to the ground through the second element.

The low-frequency signal may include either one or both of a low-frequency noise signal and a common mode signal.

The input RF signal may pass through the first element to be input to the first input terminal of the first power transistor.

The power amplifier may further include a bias circuit configured to supply a bias current to the first input terminal of the first power transistor.

The power amplifier may further include a second power transistor configured to amplify the input RF signal to produce a second amplified output RF signal and including a second input terminal configured to receive the input RF signal, and a second output terminal configured to output the second amplified output RF signal and connected to the first output terminal of the first power transistor; and a third element having an impedance value that decreases as frequency increases and having a first end connected to the second input terminal of the second power transistor, and a second end connected to the second end of the first element and the first end of the second element.

Other features and aspects will be apparent from the following detailed description, the drawings, and the claims.

### BRIEF DESCRIPTION OF THE DRAWINGS

FIG. 1 is a view illustrating a power amplifier according to an embodiment.

FIG. 2 is a view illustrating a path of a low-frequency input radio-frequency (RF) signal in the power amplifier of FIG. 1.

FIG. 3 is a view illustrating a power amplifier according to another embodiment.

FIG. 4 is a view illustrating a power amplifier according to another embodiment.

FIG. 5 is a view illustrating an example of an input transformer of FIG. 4.

FIG. 6 is a view illustrating an example of an output transformer of FIG. 4.

FIG. 7 is a view illustrating a path of a low-frequency input RF signal in the power amplifier of FIG. 4.

FIG. 8 is a view illustrating a simulation result.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION OF THE EMBODIMENTS

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated by 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Throughout the specification, a radio-frequency (RF) signal includes Wi-Fi (IEEE 802.11 family, etc.), WiMAX (IEEE 802.16 family, etc.), IEEE 802.20, LTE (long-term term evolution), Ev-DO, HSPA+, HSDPA+, HSUPA+, EDGE, GSM, GPS, GPRS, CDMA, TDMA, DECT, Bluetooth, and 3G, 4G, 5G, and any other wireless and wired protocols designated thereafter, but is not limited thereto.

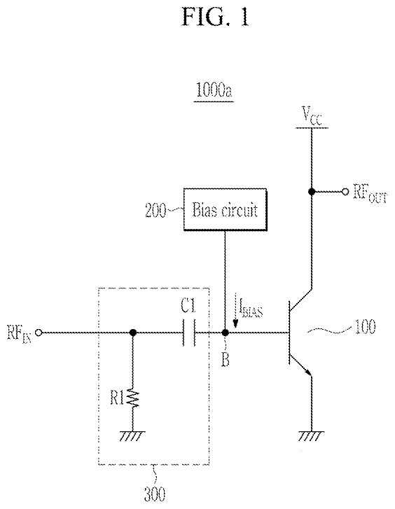

FIG. 1 is a view illustrating a power amplifier according to an embodiment.

As shown in FIG. 1, a power amplifier 1000a according to an embodiment may include a power transistor 100, a bias circuit 200, and a low-frequency reduction circuit 300.

The power transistor 100 may amplify a power of a radio-frequency (RF) signal input to an input terminal B, and then may output the amplified power to an output terminal (i.e., a collector of the power transistor 100). That is, a base of the power transistor 100 may receive the RF signal to be amplified, and the collector of the power transistor 100 may output the amplified RF signal. In FIG. 1, an input RF signal to be input to the power transistor 100 is indicated by “RF_{IN}”, and an output RF signal output from the power transistor 100 is indicated by “RFour”. An emitter of the power transistor 100 may be connected to a ground, and although not shown in FIG. 1, a resistor may be additionally connected between the emitter of the power transistor 100 and the ground. In addition, the collector of the power transistor 100 may be connected to a power source voltage V_{CC}, and the power transistor 100 may be operated by the power source voltage V_{CC}. Alternatively, the collector of the power transistor 100 may be connected to the power source voltage V_{CC} through an inductor (not shown in FIG. 1) that performs an RF choke function.

The power transistor 100 may be implemented by various transistors such as a heterojunction bipolar transistor (HBT), a bipolar junction transistor (BJT), an insulated-gate bipolar transistor (IGBT), and other types of transistors. In addition, although the power transistor 100 is shown as an n-type transistor in FIG. 1, the n-type transistor may be replaced with a p-type transistor.

The bias circuit 200 may receive a reference current (or a reference electric current) from the outside, and may generate a bias current I_{BIAS} using the reference current. The bias current I_{BIAS} may be supplied to the input terminal B of the power transistor 100, and a bias level (a bias point) of the power transistor 100 may be set by the bias current I_{BIAS}. A detailed internal configuration and a detailed operation of the bias circuit 200 are known to those skilled in the art, and thus a detailed description thereof will be omitted.

The low-frequency reduction circuit 300 may reduce a low-frequency RF signal included in an input RF signal RF_{IN}. In the power amplifier 1000a, an undesired low-frequency RF signal may be generated due to internal or external factors. For example, either one or both of a low-frequency noise and a common mode signal may be included in the input RF signal. Hereinafter, the undesired low-frequency RF signal such as the low-frequency noise or undesirable signal is referred to as “a low-frequency input RF signal”. The low-frequency reduction circuit 300 may perform a function of reducing such a low-frequency input RF signal.

As shown in FIG. 1, the low-frequency reduction circuit 300 according to an embodiment may include a capacitor C1 and a resistor R1.

One end of the capacitor C1 may be connected to the input terminal B (i.e., the base) of the power transistor 100, and the input RF signal RF_{IN} may be input to the other end of the capacitor C1. The capacitor C1 may block the low-frequency input RF signal in the input RF signal RF_{IN}. In addition, the capacitor C1 may perform a function of passing a remaining signal (i.e., a valid input RF signal to be amplified) except for a low-frequency signal in the input RF signal RF_{IN}. As an example, the capacitor C1 may perform a function of blocking a direct current (DC) component in the input RF signal RF_{IN}.

The resistor R1 may be connected between the other end of the capacitor C1 and the ground. That is, the input RF signal RF_{IN} may be input to one end of the resistor R1, and the other end of the resistor R1 may be connected to the ground. The resistor R1 may serve to bypass the low-frequency input RF signal to the ground.

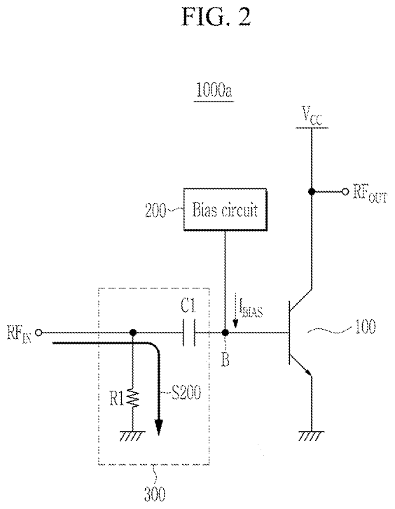

FIG. 2 is a view illustrating a path of the low-frequency input RF signal in the power amplifier 1000a of FIG. 1.

With respect to the low-frequency input RF signal, the capacitor C1 may have a high impedance value, and the resistor R1 may have a low impedance value. Considering a frequency characteristic of a capacitor, the capacitor C1 has a high impedance value as a frequency is low. However, considering a frequency characteristic of a resistor, an impedance value of the resistor R1 does not change according to the frequency characteristic. Accordingly, when a resistance value of the resistor R1 is appropriately selected, an impedance value of the capacitor C1 may be set to be higher than an impedance value of the resistor R1 for the low-frequency input RF signal. Accordingly, the low-frequency input RF signal may have a signal path S200 formed by the resistor R1 and the ground. The low-frequency input RF signal may be bypassed to the ground through the signal path S200.

On the other hand, since the input RF signal RF_{IN} has a high frequency, the input RF signal RF_{IN} may pass through the capacitor C1 to be applied to the input terminal B of the power transistor 100. Considering a frequency characteristic of a capacitor, the capacitor C1 has a low impedance value as a frequency is high. However, considering a frequency characteristic of a resistor, an impedance value of the resistor R1 does not change according to the frequency characteristic. Accordingly, when a resistance value of the resistor R1 is appropriately selected, an impedance value of the capacitor C1 may be set to be lower than an impedance value of the resistor R1 for the input RF signal RF_{IN} that is a high-frequency signal. Accordingly, the high-frequency input RF signal RF_{IN} may pass through the capacitor C1 without being bypassed to the ground through the resistor R1.

In FIG. 1, leakage of the bias current I_{BIAS} may be prevented due to a connection relationship between the capacitor C1 and the resistor R1. Unlike the connection relationship of FIG. 1, when the resistor R1 is connected to the capacitor C1 in parallel, the bias current I_{BIAS} may leak to the resistor R1 connected in parallel. However, in the connection relationship of FIGS. 1 and 2, since the resistor R1 is not connected to the capacitor C1 in parallel but is connected to the ground by a shunt, the bias current I_{BIAS} may be applied to the input terminal B of the power transistor 100 without leakage. Here, the capacitor C1 may prevent the bias current I_{BIAS} from leaking.

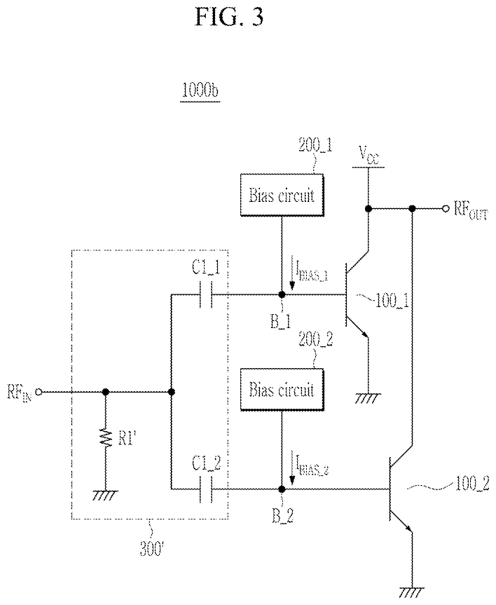

In FIG. 1, in order to increase a power gain of the power amplifier 1000a, the power transistor 100 may include a plurality of power transistors connected in parallel to each other. In this case, a method of reducing the low-frequency input RF signal will be described with reference to FIG. 3 below.

FIG. 3 is a view illustrating a power amplifier according to another embodiment.

As shown in FIG. 3, a power amplifier 1000b according to another embodiment may include a power transistor 100_1, a power transistor 100_2, a bias circuit 200_1, a bias circuit 200_2, and a low-frequency reduction circuit 300′.

The power transistor 100_1 may amplify a power of a radio-frequency (RF) signal input to an input terminal B_1, and then may output the amplified power to an output terminal (i.e., a collector of the power transistor 100_1). That is, a base of the power transistor 100_1 may receive the RF signal to be amplified, and the collector of the power transistor 100_1 may output the amplified RF signal. An emitter of the power transistor 100_1 may be connected to a ground, and although not shown in FIG. 3, a resistor may be additionally connected between the emitter of the power transistor 100_1 and the ground. In addition, the collector of the power transistor 100_1 may be connected to a power source voltage V_{CC}, and the power transistor 100_1 may be operated by the power source voltage V_{CC}. Alternatively, the collector of the power transistor 100_1 may be connected to the power source voltage V_{CC} through an inductor (not shown in FIG. 3) that performs an RF choke function.

The power transistor 100_2 may amplify a power of an RF signal input to an input terminal B_2, and then may output the amplified power to an output terminal of the power transistor 100_2 (i.e., a collector of the power transistor 100_2). That is, a base of the power transistor 100_2 may receive the RF signal to be amplified, and the collector of the power transistor 100_2 may output the amplified RF signal. An emitter of the power transistor 100_2 may be connected to a ground, and although not shown in FIG. 3, a resistor may be additionally connected between the emitter of the power transistor 100_2 and the ground. In addition, the collector of the power transistor 100_2 may be connected to the power supply voltage V_{CC}, and the power transistor 100_2 may be operated by the power supply voltage V_{CC}. Alternatively, the collector of the power transistor 100_2 may be connected to the power source voltage V_{CC} through an inductor (not shown in FIG. 3) that performs an RF choke function.

The collector of the power transistor 100_1 and the collector of the power transistor 100_2 are connected to each other, and a sum of the RF signal amplified by the power transistor 100_1 and the RF signal amplified by the power transistor 100_2 is finally output as an output RF signal RFour.

Each of the power transistors 100_1 and 1002 may be implemented by various transistors such as a heterojunction bipolar transistor (HBT), a bipolar junction transistor (BJT), an insulated-gate bipolar transistor (IGBT), and other types of transistors. In addition, although the power transistors 100_1 and 100_2 are shown as n-type transistors in FIG. 3, the n-type transistors may be replaced with p-type transistors.

The bias circuit 200_1 may receive a reference current from the outside, and may generate a bias current I_{BIAS_1} using the reference current. The bias current I_{BIAS_1} may be supplied to the input terminal B_1 of the power transistor 100_1, and a bias level (a bias point) of the power transistor 1001 may be set by the bias current I_{BIAS_1}.

The bias circuit 200_2 may receive a reference current from the outside, and may generate a bias current I_{BIAS_2} using the reference current. The bias current I_{BIAS_2} may be supplied to the input terminal B_2 of the power transistor 100_2, and a bias level (a bias point) of the power transistor 1002 may be set by the bias current I_{BIAS}_2.

A detailed internal configuration and a detailed operation of the bias circuit 200_1 and the bias circuit 200_2 are known to those skilled in the art, and thus detailed descriptions thereof will be omitted.

The low-frequency reduction circuit 300′ may reduce the low-frequency input RF signal. As shown in FIG. 3, the low-frequency reduction circuit 300′ may include a capacitor C1_1, a capacitor C1_2, and a resistor R1′.

One end of the capacitor C1_1 may be connected to the input terminal B_1 (i.e., the base) of the power transistor 100_1, and the input RF signal RF_{IN} may be input to the other end of the capacitor C1_1. The capacitor C1_1 may block the low-frequency input RF signal in the input RF signal RF_{IN}. In addition, the capacitor C1_1 may perform a function of passing a remaining signal (i.e., a valid input RF signal to be amplified) except for a low-frequency signal in the input RF signal RF_{IN}. That is, the capacitor C1_1 of FIG. 3 may perform a function similar to that of the capacitor C1 of FIG. 1.

One end of the capacitor C1_2 may be connected to the input terminal B_2 (i.e., the base) of the power transistor 100_2, and the input RF signal RF_{IN} may be input to the other end of the capacitor C1_2. That is, the other end of the capacitor C1_2 may be connected to the other end of the capacitor C1_1. The capacitor C1_2 may block the low-frequency input RF signal in the input RF signal RF_{IN}. In addition, the capacitor C1_2 may perform a function of passing a remaining signal (i.e., a valid input RF signal to be amplified) except for a low-frequency signal in the input RF signal RF_{IN}. That is, the capacitor C1_2 of FIG. 3 may perform a function similar to that of the capacitor C1 of FIG. 1.

One end of the resistor R1′ may be connected to the other end of the capacitor C1_1 and the other end of the capacitor C1_2, and the other end of the resistor R1′ may be connected to the ground. That is, the input RF signal RF_{IN} may be input to one end of the resistor R1′, and the other end of the resistor R1′ may be connected to the ground. The resistor R1′ may serve to bypass the low-frequency input RF signal to the ground. With respect to the low-frequency input RF signal, each of the capacitor C1_1 and the capacitor C1_2 may have a high impedance value, and the resistor R1′ may have a low impedance value. Accordingly, the low-frequency input RF signal may be removed through a signal path formed by the resistor R1′ and the ground. The resistor R1′ may be commonly used with the two power transistors 100_1 and 100_2 so that the number of resistors used to reduce the low-frequency input RF signal is reduced.

Although a case in which there are two power transistors in order to increase a power gain in the power amplifier 1000b of FIG. 3 is described, the case may be extended and applied even when there are three or more power transistors.

The method of reducing the low-frequency input RF signal described in FIGS. 1 to 3 may be applied to a transformer-based push-pull power amplifier (PA) that will be described below.

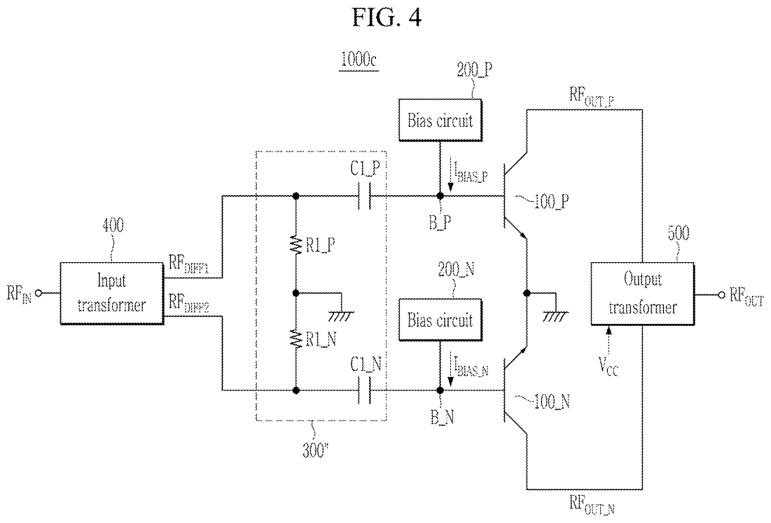

FIG. 4 is a view illustrating a power amplifier according to another embodiment.

As illustrated in FIG. 4, a power amplifier 1000c according to another embodiment may include a power transistor 100_P, a power transistor 100_N, a bias circuit 200_P, a bias circuit 200_N, a low-frequency reduction circuit 300″, an input transformer 400, and an output transformer 500.

The input transformer 400 may receive an input RF signal RF_{IN} that is a singe-ended signal, and may convert the input RF signal RF_{IN} that is a single-ended signal to two differential signals and output the converted differential signals. The two differential signals may have a phase difference of 180 degrees between each other. Hereinafter, the two differential signals are referred to as a first differential signal RF_{DIFF1} and a second differential signal RF_{DIFF2}. The input transformer 400 may be implemented by a balun transformer.

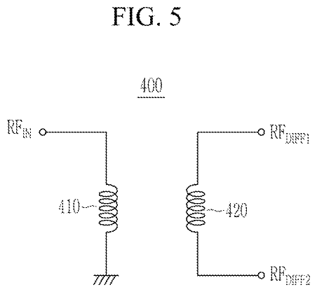

FIG. 5 is a view illustrating an example of the input transformer 400 of FIG. 4.

As shown in FIG. 5, the input transformer 400 may include a primary side coil 410 and a secondary side coil 420.

The input RF signal RF_{IN} may be input to one end of the primary coil 410, and the other end of the primary coil 410 may be connected to a ground.

The first differential signal RF_{DIFF1} may be output from one end of the secondary side coil 420, and the second differential signal RF_{DIFF2} may be output from the other end of the secondary side coil 420. The first differential signal RF_{DIFF1} and the second differential signal RF_{DIFF2} may have the same amplitude, and may have a phase difference of 180 degrees between each other.

However, since balancing is not perfect during a signal conversion process of the input transformer 400, amplitude and phase imbalance may occur. Accordingly, a common mode signal may be generated in an output signal of the input transformer 400. That is, the first differential signal RF_{DIFF1} and the second differential signal RF_{DIFF2} may include the common mode signal. Since the common mode signal generally has a low frequency, the common mode signal may be an example of the low-frequency input RF signal described in FIG. 1. However, in FIG. 4, low-frequency noise may also be generated as an example of the low-frequency input RF signal. Hereinafter, for convenience of description, a case where the low-frequency input RF signal is the common mode signal will be described, but the description may also be applicable to another low-frequency input RF signal. When the common mode signal (the low-frequency input RF signal) is input to the power amplifier 1000c, the power amplifier 1000c may oscillate. To prevent the oscillation, the low-frequency reduction circuit 300′ may perform a function of reducing the common mode signal (the low-frequency input RF signal).

The power transistor 100_P may amplify a power of the first differential signal RF_{DIFF1} input to an input terminal B_P, and then may output the amplified power to an output terminal (i.e., a collector of the power transistor 100_P). That is, a base of the power transistor 100_P may receive the first differential signal RF_{DIFF1} to be amplified, and the collector of the power transistor 100_P may output the amplified RF signal. In FIG. 4, an output RF signal of the power transistor 100_P is indicated by “RF_{OUT_P}”. An emitter of the power transistor 100_P may be connected to a ground, and although not shown in FIG. 4, a resistor may be additionally connected between the emitter of the power transistor 100_P and the ground. In addition, the collector of the power transistor 100_P may receive a power supply voltage V_{CC} through the output transformer 500, and the power transistor 100_P may be operated by the power supply voltage V_{CC}.

The power transistor 100_N may amplify a power of the second differential signal RF_{DIFF2} input to an input terminal B_N, and then may output the amplified power to an output terminal (i.e., a collector of the power transistor 100_N). That is, a base of the power transistor 100_N may receive the second differential signal RF_{DIFF2} to be amplified, and the collector of the power transistor 100_N may output the amplified RF signal. In FIG. 4, an output RF signal of the power transistor 100_N is indicated as “RF_{OUT_N}”. An emitter of the power transistor 100_N may be connected to the ground, and although not shown in FIG. 4, a resistor may be additionally connected between the emitter of the power transistor 100_N and the ground. In addition, the collector of the power transistor 100_N may receive the power supply voltage V_{CC} through the output transformer 500, and the power transistor 100_N may be operated by the power supply voltage V_{CC}.

Each of the power transistors 100_P and 100_N may be implemented by various transistors such as a heterojunction bipolar transistor (HBT), a bipolar junction transistor (BJT), an insulated-gate bipolar transistor (IGBT), and other types of transistors. In addition, although the power transistors 100_P and 100_N are shown as an n-type transistor in FIG. 4, the n-type transistor may be replaced with a p-type transistor.

The bias circuit 200_P may receive a reference current from the outside, and may generate a bias current I_{BIAS_P} using the reference current. The bias current I_{BIAS_P} may be supplied to the input terminal B_P of the power transistor 100_P, and a bias level (a bias point) of the power transistor 100_P may be set by the bias current I_{BIAS_P}.

The bias circuit 200_N may receive a reference current from the outside, and may generate a bias current I_{BIAS_N} using the reference current. The bias current I_{BIAS_N} may be supplied to the input terminal B_N of the power transistor 100_N, and a bias level (a bias point) of the power transistor 100_N may be set by the bias current I_{BIAS_N}.

A detailed internal configuration and a detailed operation of the bias circuit 200_P and the bias circuit 200_N are known to those skilled in the art, and thus detailed descriptions thereof will be omitted.

The output transformer 500 may receive the output RF signal RF_{OUT_P} of the power transistor 100_P and the output RF signal RF_{OUT_N} of the power transistor 100_N. The output transformer 500 may combine these two received signals to finally output an output RF signal RF_{OUT}. The output transformer 500 may also receive the power supply voltage V_{CC} from the outside, and may supply the power supply voltage V_{CC} to the collector of the power transistor 100_P and the collector of the power transistor 100_N.

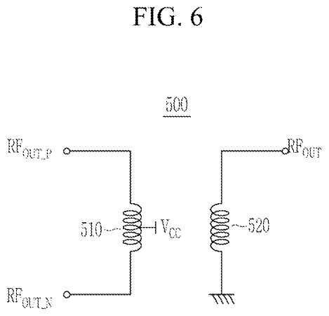

FIG. 6 is a view illustrating an example of the output transformer 500 of FIG. 4.

As shown in FIG. 6, the output transformer 500 may include a primary side coil 510 and a secondary side coil 520.

The output RF signal RF_{OUT_P} of the power transistor 100_P may be input to one end of the primary coil 510, and the output RF signal RF_{OUT_N} of the power transistor 100_N may be input to the other end of the primary coil 510. That is, the collector of the power transistor 100_P may be connected to one end of the primary coil 510, and the collector of the power transistor 100_N may be connected to the other end of the primary coil 510. In addition, the primary coil 510 may have an intermediate tap, and the power supply voltage V_{CC} may be applied to the intermediate tap of the primary coil 510. The power supply voltage V_{CC} may be supplied to the collector of the power transistor 100_P through the intermediate tap of the primary coil 510. In addition, the power voltage V_{CC} may be supplied to the collector of the power transistor 100_N through the intermediate tap of the primary coil 510.

The output RF signal RF_{OUT} may be output from one end of the secondary coil 520, and the other end of the secondary coil 520 may be connected to the ground. The output RF signal RF_{OUT} is a signal obtained by combining the output RF signal RF_{OUT_P} of the power transistor 100_P and the output RF signal RF_{OUT_N} of the power transistor 100_N.

The output RF signal RF_{OUT_P} of the power transistor 100_P and the output RF signal RF_{OUT_N} of the power transistor 100_N may have a phase difference of 180 degrees between each other. The output transformer 500 may convert the two output RF signals RF_{OUT_P} and RF_{OUT_N} having a phase difference of 180 degrees between each other to a single-ended signal having twice the amplitude of the output RF signals RF_{OUT_P} and RF_{OUT_N}.

The low-frequency reduction circuit 300″ may reduce the common mode signal that is a low-frequency signal. As illustrated in FIG. 4, the low-frequency reduction circuit 300″ may include a capacitor C1_P, a capacitor C1_N, a resistor R1_P, and a resistor R1_N.

One end of the capacitor C1_P may be connected to the input terminal B_P (i.e., the base) of the power transistor 100_P, and the first differential signal RF_{DIFF1} may be input to the other end of the capacitor C1_P. The capacitor C1_P may block the common mode signal in the first differential signal RF_{DIFF1}. In addition, the capacitor C1_P may perform a function of passing a remaining signal (i.e., a valid input RF signal to be amplified) except for the common mode signal (i.e., the low-frequency signal) in the first differential signal RF_{DIFF1}. That is, the capacitor C1_P of FIG. 4 may perform a function similar to that of the capacitor C1 of FIG. 1.

One end of the capacitor C1_N may be connected to the input terminal B_N (i.e., the base) of the power transistor 100_N, and the second differential signal RF_{DIFF2} may be input to the other end of the capacitor C1_N. The capacitor C1_N may block the common mode signal in the second differential signal RF_{DIFF2}. In addition, the capacitor C1_N may perform a function of passing a remaining signal (i.e., a valid input RF signal to be amplified) except for the common mode signal (i.e., the low-frequency input RF signal) in the second differential signal RF_{DIFF2}. That is, the capacitor C1_N of FIG. 4 may perform a function similar to that of the capacitor C1 of FIG. 1.

One end of the resistor R1_P may be connected to the other end of the capacitor C1_P, and the other end of the resistor R1_P may be connected to the ground. That is, the first differential signal RF_{DIFF1} may be input to one end of the resistor R1_P, and the other end of the resistor R1_P may be connected to the ground. The resistor R1_P may serve to bypass the low-frequency input RF signal (e.g., the common mode signal) to the ground. With respect to the low-frequency input RF signal, the capacitor C1_P may have a high impedance value, and the resistor R1_P may have a low impedance value. Accordingly, the low-frequency input RF signal may be through a signal path formed by the resistor R1_P and the ground.

One end of the resistor R1_N may be connected to the other end of the capacitor C1_N, and the other end of the resistor R1_N may be connected to the ground. That is, the second differential signal RF_{DIFF2} may be input to one end of the resistor R1_N, and the other end of the resistor R1_N may be connected to the ground. The resistor R1_N may serve to bypass the low-frequency input RF signal (e.g., the common mode signal) to the ground. With respect to the low-frequency input RF signal, the capacitor C1_N may have a high impedance value, and the resistor R1_N may have a low impedance value. Accordingly, the low-frequency input RF signal may be removed through a signal path formed by the resistor R1_N and the ground.

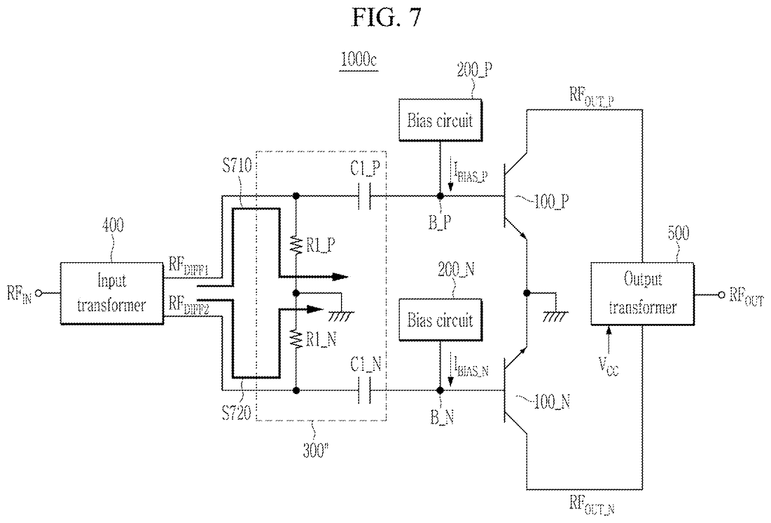

FIG. 7 is a view illustrating a path of the low-frequency input RF signal in the power amplifier 1000c of FIG. 4.

With respect to the low-frequency input RF signal, each of the capacitor C1_P and the capacitor C1_N may have a high impedance value, and each of the resistor R1_P and the resistor R1_N may have a low impedance value. Considering a frequency characteristic of a capacitor, each of the capacitor C1_P and the capacitor C1_N has a high impedance value as a frequency is low. However, considering a frequency characteristic of a resistor, impedance values of the resistor R1_P and the resistor R1_N do not change according to the frequency characteristic. Accordingly, the low-frequency input RF signal included in the first differential signal RF_{DIFF1} may have a signal path S710 formed by the resistor R1_P and the ground. In addition, the low-frequency input RF signal included in the second differential signal RF_{DIFF2} may have a signal path S720 formed by the resistor R1_N and the ground. Accordingly, the low-frequency input RF signal (the common mode signal included in the first differential signal RF_{DIFF1} and the second differential signal RF_{DIFF}) may be bypassed to the ground through the signal paths S710 and S720.

On the other hand, since the first differential signal RF_{DIFF1} has a high frequency, the first differential signal RF_{DIFF1} may pass through the capacitor C1_P to be applied to the input terminal B_P of the power transistor 100_P. Considering a frequency characteristic of a capacitor, the capacitor C1_P has a low impedance value as a frequency is high. However, considering a frequency characteristic of a resistor, an impedance value of the resistor R1_P does not change according to the frequency characteristic. Accordingly, when a resistance value of the resistor R1_P is appropriately selected, an impedance value of the capacitor C1_P may be set to be lower than an impedance value of the resistor R1_P for the first differential signal RF_{DIFF1} that is a high-frequency signal. Accordingly, the first differential signal RF_{DIFF1} may pass through the capacitor C1_P without being bypassed to the ground through the resistor R1_P.

In addition, since the second differential signal RF_{DIFF2} has a high frequency, the second differential signal RF_{DIFF2} may pass through the capacitor C1_N to be applied to the input terminal B_N of the power transistor 100_N. Considering a frequency characteristic of a capacitor, the capacitor C1_N has a low impedance value as a frequency is high. However, considering a frequency characteristic of a resistor, an impedance value of the resistor R1_N does not change according to the frequency characteristic. Accordingly, when a resistance value of the resistor R1_N is appropriately selected, an impedance value of the capacitor C1_N may be set to be lower than an impedance value of the resistor R1_N for the second differential signal RF_{DIFF2} that is a high-frequency signal. Accordingly, the second differential signal RF_{DIFF2} may pass through the capacitor C1_N without being bypassed to the ground through the resistor R1_N.

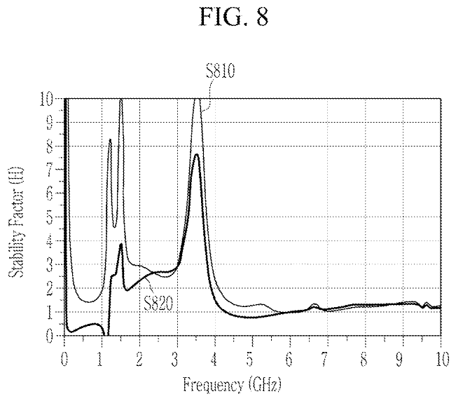

FIG. 8 is a view illustrating a simulation result.

In FIG. 8, a horizontal axis represents a frequency, and a vertical axis represents a stability factor. S810 shows a simulation result for the power amplifier 1000c of FIG. 4, and S820 shows a simulation result for a general power amplifier to which the low-frequency reduction circuit 300″ of FIG. 4 is not applied.

The stability factor is an indicator of a possibility of oscillation. When the stability factor has a value of 1 or more in an entire frequency band, the power amplifier is in a stable state (i.e., a low possibility of oscillation). When the stability factor has a value of 1 or less, the power amplifier has a possibility of oscillation.

Referring to S820, the general power amplifier has a value of the stability factor of 1 or less at 1.2 GHz or less. That is, the general power amplifier may oscillate at 1.2 GHz or less.

In contrast, referring to S810, the power amplifier 1000c of FIG. 4 has a value of the stability factor of 1 or more in an entire frequency band. That is, in the power amplifier 1000c of FIG. 4 to which the low-frequency reduction circuit 300″ is applied, the stability factor is improved in a low-frequency band of 1.2 GHz or less.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and are not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A power amplifier configured to amplify an input radio-frequency (RF) signal, the power amplifier comprising:
a first power transistor comprising an input terminal;
a first capacitor having a first end connected to the input terminal of the first power transistor; and
a resistor having a first end connected to a second end of the first capacitor and a second end connected to a ground,
wherein the input RF signal is input to the second end of the first capacitor and the first end of the resistor.

2. The power amplifier of claim 1, wherein a low-frequency signal comprising a noise included in the input RF signal is bypassed to the ground through the resistor.

3. The power amplifier of claim 2, wherein the low-frequency signal comprises either one or both of a low-frequency noise signal and a common mode signal.

4. The power amplifier of claim 2, wherein the input RF signal passes through the first capacitor to be input to the input terminal of the first power transistor.

5. The power amplifier of claim 1, further comprising a bias circuit configured to supply a bias current to the input terminal of the first power transistor.

6. The power amplifier of claim 1, further comprising:
a second power transistor comprising an input terminal and an output terminal connected to an output terminal of the first power transistor; and
a second capacitor connected between the first end of the resistor and the input terminal of the second power transistor.

7. The power amplifier of claim 6, wherein the input RF signal passes through the first capacitor to be input to the input terminal of the first power transistor, and passes through the second capacitor to be input to the input terminal of the second power transistor.

8. The power amplifier of claim 6, further comprising:
a first bias circuit configured to supply a first bias current to the input terminal of the first power transistor; and
a second bias circuit configured to supply a second bias current to the input terminal of the second power transistor.

9. A power amplifier comprising:
a first power transistor comprising an input terminal;
a second power transistor comprising an input terminal;
a first capacitor having a first end connected to the input terminal of the first power transistor;
a first resistor having a first end connected to a second end of the first capacitor and a second end connected to a ground;
a second capacitor having a first end connected to the input terminal of the second power transistor; and
a second resistor having a first end connected to a second end of the second capacitor and a second end connected to the ground.

10. The power amplifier of claim 9, further comprising an input transformer configured to convert an input radio-frequency (RF) signal to a first differential signal and a second differential signal,
wherein the first differential signal is input to the second end of the first capacitor and the first end of the first resistor, and the second differential signal is input to the second end of the second capacitor and the first end of the second resistor.

11. The power amplifier of claim 10, wherein a low-frequency signal comprising a noise included in the first differential signal is bypassed to the ground through the first resistor, and a low-frequency signal comprising a noise included in the second differential signal is bypassed to the ground through the second resistor.

12. The power amplifier of claim 11, wherein the low-frequency signal comprises either one or both of a low-frequency noise signal and a common mode signal.

13. The power amplifier of claim 11, wherein the first differential signal passes through the first capacitor to be input to the input terminal of the first power transistor, and the second differential signal passes through the second capacitor to be input to the input terminal of the second power transistor.

14. The power amplifier of claim 10, further comprising an output transformer configured to combine an output signal of the first power transistor with an output signal of the second power transistor.

15. A power amplifier comprising:
a first power transistor configured to amplify an input radio-frequency (RF) signal to produce a first amplified output RF signal and comprising a first input terminal configured to receive the input RF signal, and a first output terminal configured to output the first amplified output RF signal;
a first element having an impedance value that decreases as frequency increases and having a first end connected to the first input terminal of the first power transistor; and
a second element having an impedance value that is substantially independent of frequency and having a first end connected to a second end of the first element and a second end connected to a ground.

16. The power transistor of claim 15, wherein a low-frequency signal included in the input RF signal is bypassed to the ground through the second element.

17. The power amplifier of claim 16, wherein the low-frequency signal comprises either one or both of a low-frequency noise signal and a common mode signal.

18. The power amplifier of claim 16, wherein the input RF signal passes through the first element to be input to the first input terminal of the first power transistor.

19. The power amplifier of claim 15, further comprising a bias circuit configured to supply a bias current to the first input terminal of the first power transistor.

20. The power amplifier of claim 15, further comprising:
a second power transistor configured to amplify the input RF signal to produce a second amplified output RF signal and comprising a second input terminal configured to receive the input RF signal, and a second output terminal configured to output the second amplified output RF signal and connected to the first output terminal of the first power transistor; and
a third element having an impedance value that decreases as frequency increases and having a first end connected to the second input terminal of the second power transistor, and a second end connected to the second end of the first element and the first end of the second element.
